(19) United States
(12) Patent Application Publication
(10) Pub. No.: US 2019/0391189 A1
(43) Pub. Date: Dec. 26, 2019

(54) COLLECTED CURRENT MONITORING DEVICE

(71) Applicant: CENTRAL JAPAN RAILWAY COMPANY, Nagoya-shi (JP)

(72) Inventors: Hironobu Sunami, Nagoya-shi (JP); Kazuki Tanaka, Nagoya-shi (JP); Yoshitsugu Morita, Nagoya-shi (JP); Isamu Makara, Nagoya-shi (JP); Yuichi Ahiko, Nagoya-shi (JP); Kotaro Nakamura, Nagoya-shi (JP); Hiroki Shimoyama, Nagoya-shi (JP)

(21) Appl. No.: 16/447,319

(22) Filed: Jun. 20, 2019

(30) Foreign Application Priority Data
Jun. 22, 2018 (JP) 2018-118835

(51) Int. Cl. G01R 19/25; G01R 31/02

(52) U.S. Cl. CPC G01R 19/2506; G01R 31/025

(57) ABSTRACT

A collected current monitoring device is provided which includes a current-value obtaining unit that obtains a current value I1 and a current value I2, a first RMS-calculation unit that calculates a root mean square RMS1, a second RMS-calculation unit that calculates a root mean square RMS2, an Iu calculation unit that calculates an imbalance current Iu, a change calculation unit that calculates an amount of change ΔIu, an average calculation unit that calculates a time average value aveΔIu, a determining unit that determines whether the time average value aveΔIu is larger than a threshold value, and a signal output unit that outputs an abnormality signal when the time average value aveΔIu is larger than the threshold value.

### CROSS-REFERENCE TO RELATED APPLICATIONS

The present application claims the benefit of Japanese Patent Application No. 2018-118835 filed on Jun. 22, 2018 with the Japan Patent Office, the entire disclosure of which is incorporated herein by reference.

### BACKGROUND

The present disclosure relates to a collected current monitoring device.

A railroad vehicle is provided with a current collector on its roof. For example, Japanese Patent No. 4386253 discloses a current collector which has a collector shoe supported by a current collecting arm. The collector shoe has a shoe body, and a sliding plate attached to a top surface of the shoe body. According to this current collector, the sliding plate of the collector shoe is pressed against an underside of an overhead catenary line, so that electric current is collected from the overhead catenary line to the railroad vehicle.

### SUMMARY

When a current collector, among a plurality of current collectors, is unable to collect electric current, such a situation is called contact loss. The contact loss occasionally occurs on a current collector mounted on a front side in a running direction of a railroad vehicle of the plurality of current collectors when an overhead catenary line is frozen or frosted. If another current collector experiences the contact loss for some reasons when one current collector is experiencing the contact loss, it causes an electric are and damages the shoe body.

Therefore, a collected current monitoring device is demanded which allows detection of a situation in which the electric arc is likely to occur. Since the electric arc is likely to occur when the contact loss is occurring, it is considered to detect a situation in which the electric arc is likely to occur based on imbalance of collected current in the plurality of current collectors.

However, as a result of actual measurement of the collected current in various situations, it was found that imbalance of the collected current occurs regardless of presence or absence of the electric are. Therefore, in case of detecting a situation in which the electric arc is likely to occur based only on the imbalance of the collected current, reliability of the evaluation on whether the electric arc is likely to occur can decrease.

In one aspect of the present disclosure, it is desirable to provide a collected current monitoring device that allows detection of a situation in which an electric arc is likely to occur with high precision.

One aspect of the present disclosure provides a collected current monitoring device comprising a current-value obtaining unit that obtains a current value I1 of collected current flowing through a first current collector, and a current value I2 of collected current flowing through a second current collector, a first RMS-calculation unit that calculates a root mean square RMS1 of the current value I1, a second RMS-calculation unit that calculates a root mean square RMS2 of the current value I2, an Iu calculation unit that calculates an imbalance current Iu which is a value obtained by subtracting one of the root mean square RMS1 and the root mean square RMS2 from the other, a change calculation unit that calculates an amount of change ΔIu which is an amount of change per unit time in the imbalance current Iu, an average calculation unit that calculates a time average value aveΔIu which is a time average value in a preset time P, of an absolute value of the amount of change ΔIu, a determining unit that determines whether the time average value aveΔIu is larger than a preset threshold value, and a signal output unit that outputs an abnormality signal when the determining unit determines that the time average value aveΔIu is larger than the threshold value.

According to the collected current monitoring device of the present disclosure, when the first current collector or the second current collector is in a situation in which an electric are is likely to occur (for example, situation in which an overhead catenary line is frozen or frosted), the abnormality signal can be outputted. Also, the collected current monitoring device of the present disclosure can control output of the abnormality signal when the first current collector and the second current collector are in a situation in which the electric arc is unlikely to occur.

Another aspect of the present disclosure provides a collected current monitoring device comprising a current-value obtaining unit that obtains a current value I1 of collected current flowing through a first current collector, and a current value I2 of collected current flowing through a second current collector, a first RMS-calculation unit that calculates a root mean square RMS1 of the current value I1, a second RMS-calculation unit that calculates a root mean square RMS2 of the current value I2, an Iu calculation unit that calculates an imbalance current Iu which is a value obtained by subtracting one of the root mean square RMS1 and the root mean square RMS2 from the other, a change calculation unit that calculates an amount of change ΔIu which is an amount of change per unit time in the imbalance current Iu, an average calculation unit that calculates a time average value aveΔIu which is a time average value in a preset time P, of an absolute value of the amount of change ΔIu, an Iu average calculation unit that calculates a time average value aveIu which is a time average value in a preset time Q, of the imbalance current Iu, a determining unit that determines whether a combination of the time average value aveIu and the time average value aveΔIu satisfies a preset abnormality condition, and a signal output unit that outputs an abnormality signal when the determining unit determines that the combination satisfies the abnormality condition.

The abnormality condition is a condition that, in a two-dimensional space defined by a first axis representing the absolute value of the time average value aveIu and a second axis representing the time average value aveΔIu, the combination of the time average value aveIu and the time average value aveΔIu is outside a normal region defined below.

Normal region: a region including a region surrounded by a boundary line passing through a positive intercept in the first axis and a positive intercept in the second axis, the first axis, and the second axis.

According to the collected current monitoring device of the present disclosure, when the first current collector or the second current collector is in a situation in which an electric are is likely to occur (for example, situation in which an overhead catenary line is frozen or frosted), the abnormality signal can be outputted. Also, the collected current monitoring device of the present disclosure can control output of the abnormality signal when the first current collector and the second current collector are in a situation in which the electric arc is unlikely to occur.

Another aspect of the present disclosure provides a collected current monitoring device comprising a current-value obtaining unit that obtains a current value I1 of collected current flowing through a first current collector, and a current value I2 of collected current flowing through a second current collector, a first RMS-calculation unit that calculates a root mean square RMS1 of the current value I1, a second RMS-calculation unit that calculates a root mean square RMS2 of the current value I2, an Iu calculation unit that calculates an imbalance current Iu which is a value obtained by subtracting one of the root mean square RMS1 and the root mean square RMS2 from the other, a change calculation unit that calculates an amount of change ΔIu which is an amount of change per unit time in the imbalance current Iu, an average calculation unit that calculates a time average value aveΔIu which is a time average value in a preset time P, of an absolute value of the amount of change ΔIu, an Iu average calculation unit that calculates a time average value ave|Iu| which is a time average value in a preset time Q, of an absolute value of the imbalance current Iu, a determining unit that determines whether a combination of the time average value ave|Iu| and the time average value aveΔIu satisfies a preset abnormality condition, and a signal output unit that outputs an abnormality signal when the determining unit determines that the combination satisfies the abnormality condition. The abnormality condition is a condition that, in a two-dimensional space defined by a first axis representing the time average value ave|Iu| and a second axis representing the time average value aveΔIu, the combination of the time average value ave|Iu| and the time average value aveΔIu is outside a normal region defined below.

Normal region: a region including a region surrounded by a boundary line passing through a positive intercept in the first axis and a positive intercept in the second axis, the first axis, and the second axis. According to the collected current monitoring device of the present disclosure, when the first current collector or the second current collector is in a situation in which an electric arc is likely to occur (for example, situation in which an overhead catenary line is frozen or frosted), the abnormality signal can be outputted. Also, the collected current monitoring device of the present disclosure can control output of the abnormality signal when the first current collector and the second current collector are in a situation in which an electric arc is unlikely to occur.

### BRIEF DESCRIPTION OF THE DRAWINGS

An example embodiment of the present disclosure will be described hereinafter with reference to the accompanying drawings, in which:

FIG. 1 is a block diagram showing configuration of a collected current monitoring device and other devices;

FIG. 2 is a block diagram showing functional configuration of the collected current monitoring device;

FIG. 3 is a flowchart showing a process executed by the collected current monitoring device;

FIG. 4A is a graph showing a first current I1 in a large arc situation;

FIG. 4B is a graph showing a second current I2 in the large arc situation;

FIG. 4C is a graph showing a root mean square RMS1 in the large arc situation;

FIG. 4D is a graph showing a root mean square RMS2 in the large arc situation;

FIG. 4E is a graph showing an imbalance current Iu in the large arc situation;

FIG. 4F is a graph showing a time average value aveΔIu in the large arc situation;

FIG. 5A is a graph showing the first current I1 in a normal situation;

FIG. 5B is a graph showing the second current I2 in the normal situation;

FIG. 5C is a graph showing the root mean square RMS1 in the normal situation;

FIG. 5D is a graph showing the root mean square RMS2 in the normal situation;

FIG. 5E is a graph showing the imbalance current Iu in the normal situation;

FIG. 5F is a graph showing the time average value aveΔIu in the normal situation;

FIG. 6 is a block diagram showing functional configuration of the collected current monitoring device;

FIG. 7 is a flowchart showing a process executed by the collected current monitoring device;

FIG. 8 is an explanatory view showing a two-dimensional space defined by a first axis and a second axis;

FIG. 9 is a graph showing a result plotted on a two-dimensional space, of a combination of a time average value aveIu and the time average value aveΔIu in the large arc situation;

FIG. 10 is a graph showing a result plotted on the two-dimensional space, of the combination of the time average value aveIu and the time average value aveΔIu in the normal situation;

FIG. 11 is an explanatory view showing another form of a boundary line and a normal region; and

FIG. 12 is an explanatory view showing another form of the normal region.

### DETAILED DESCRIPTION OF THE PREFERRED EMBODIMENTS

### First Embodiment

1. Configuration of Collected Current Monitoring Device 1

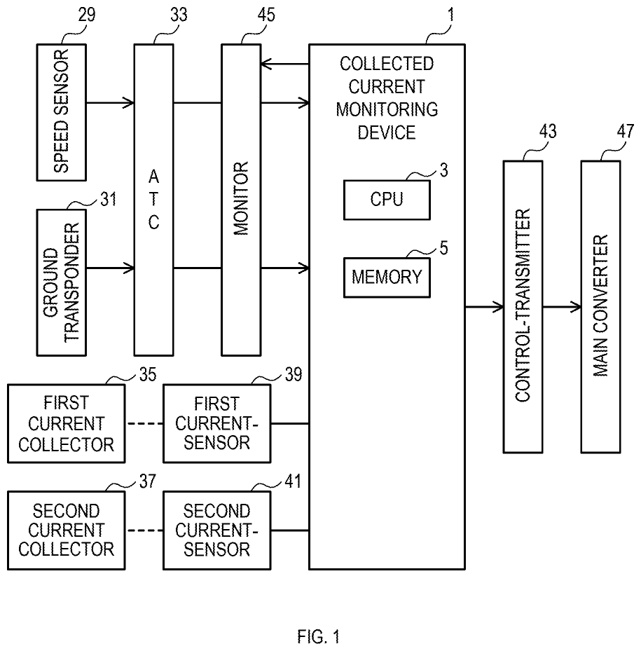

A collected current monitoring device 1 is mounted on a railroad vehicle. As shown in FIG. 1, the collected current monitoring device 1 is a microcomputer including a CPU 3 and a memory 5. The memory 5 may be, for example, a semiconductor memory such as a RAM, a ROM, and a flash memory. Various functions of the collected current monitoring device 1 are enabled by the CPU 3 running programs stored in the memory 5.

Part or all of the functions of the collected current monitoring device 1 may be in hardware using one or more ICs or the like. Also, the collected current monitoring device 1 may include hardware such as an electronic circuit, instead of/in addition to the microcomputer. The electronic circuit can include at least one of a digital circuit and an analog circuit.

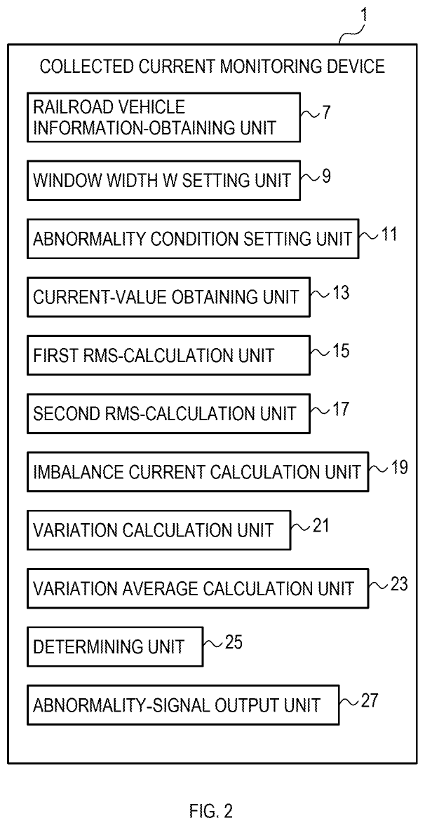

As those functions enabled by the CPU 3 running the programs, the collected current monitoring device 1 has a railroad vehicle information-obtaining unit 7 (hereinafter, information-obtaining unit 7), a window width W setting unit 9 (hereinafter, W setting unit 9), an abnormality condition setting unit 11 (hereinafter, condition setting unit 11), a current-value obtaining unit 13, a first RMS-calculation unit 15, a second RMS-calculation unit 17, an imbalance current calculation unit 19 (hereinafter, Iu calculation unit 19), a change calculation unit 21, a change average calculation unit 23 (hereinafter, average calculation unit 23), a determining unit 25, and an abnormality-signal output unit 27 (hereinafter, signal output unit 27), as shown in FIG. 2.

In addition to the collected current monitoring device 1, the railroad vehicle has a speed sensor 29, a ground transponder 31, an ATC (automatic train control) 33, a first current collector 35, a second current collector 37, a first current-sensor 39, a second current-sensor 41, a control-transmitter 43, a monitor 45, and a main converter 47.

The speed sensor 29 detects a speed V of the railroad vehicle and transmits the detected speed V to the ATC 33. The ATC 33 integrates the speed V by time and constantly estimates a position PO of the railroad vehicle. The ground transponder 31 transmits position-correction information to the ATC 33. The position-correction information is a precise positional information of the railroad vehicle. The ATC 33 uses the position-correction information to properly correct the position PO that is estimated as explained above. The ATC 33 transmits the speed V and the position PO to the collected current monitoring device 1 via the monitor 45. The monitor 45 displays the speed V and the position PO.

The first current-sensor 39 detects a current value I1 of collected current flowing through the first current collector 35 and transmits the detected current value I1 to the collected current monitoring device 1. The second current-sensor 41 detects a current value I2 of collected current that flows through the second current collector 37 and transmits the detected current value I2 to the collected current monitoring device 1. The first current collector 35 is mounted on an m^{th} car of the railroad vehicle, and the second current collector 37 is mounted on an nt^{h} car of the railroad vehicle. Note that m and n are both natural numbers from 1 to 16, where m is smaller than n.

The monitor 45 and the control-transmitter 43 receive an abnormality signal described later. In response to receiving the abnormality signal, the control-transmitter 43 transmits the abnormality signal to the main converter 47. The monitor 45 is located at a driver's seat. A driver of the railroad vehicle can watch a displayed image on the monitor 45. In response to receiving the abnormality signal, the monitor 45 displays an abnormality notification image. The abnormality notification image is a unique image displayed when the abnormality signal is received. The main converter 47 enables notch control in response to receiving the abnormality signal. The notch control is for controlling the speed or acceleration of the railroad vehicle.

2. Process Executed by Collected Current Monitoring Device 1

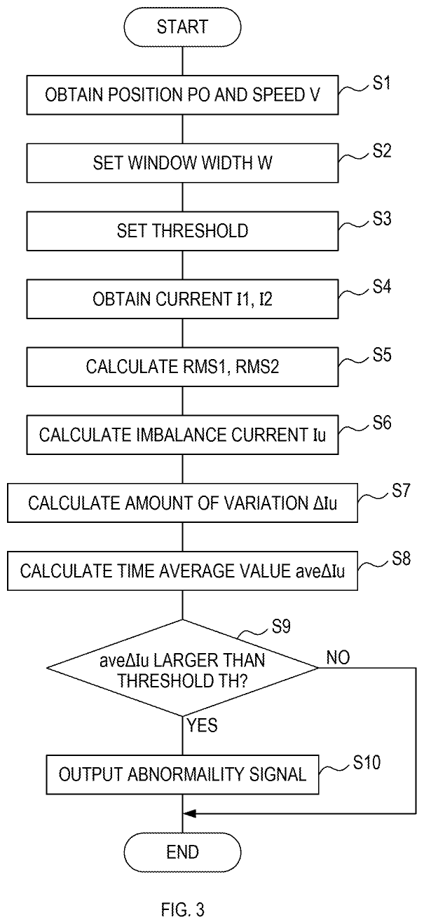

Process repeated by the collected current monitoring device 1 every fixed cycle Δt will be explained with reference to FIG. 3. Note that Δt is a positive number, for example, 2 msec.

In Step 1 in FIG. 3, the information-obtaining unit 7 obtains the position PO and the speed V from the ATC 33.

In Step 2, the W setting unit 9 sets a window width W in accordance with the position PO and the speed V obtained in Step 1. The window width W is a length of interval, the integral of which is used to calculate a root mean square RMS1 and a root mean square RMS2 in Step 5, which will be explained later. The unit of the window width W is msec. The W setting unit 9 has, in advance, a table which associates the position PO and the speed V with the window width W and uses the table to set the window width W.

The range of the window width W in the table is, for example, from 10 msec to 1000 msec. The table can be created, for example, by first creating a base table and then repeating a cycle of using the base table, assessing the result of the use, and revising the base table based on the assessment result. Revision in this cycle is made so that the abnormality signal is likely to be outputted in a large arc situation described later, and the abnormality signal is unlikely to be outputted in a normal situation described later.

In Step 3, the condition setting unit 11 sets a threshold value TH in accordance with the position PO and the speed V obtained in Step 1. The threshold value TH is a positive value. The threshold value TH is used in Step 9 described later. The condition setting unit 11 has, in advance, a table which associates the position PO and the speed V with the threshold value TH and uses the table to set the threshold value TH.

The table can be created, for example, by first creating a base table and then repeating a cycle of using the base table, assessing the result of the use, and revising the base table based on the assessment result. Revision in this cycle is made so that the abnormality signal is likely to be outputted in the large arc situation described later, and the abnormality signal is unlikely to be outputted in the normal situation described later.

In Step 4, the current-value obtaining unit 13 uses the first current-sensor 39 to obtain the first current value I1 and uses the second current-sensor 41 to obtain the second current value I2.

In Step 5, the first RMS-calculation unit 15 calculates the root mean square RMS1 of the first current value I1, which was obtained in Step 4, in the window width W. The window width W used in this calculation is the window width W that was set in Step 2.

Also in Step 5, the second RMS-calculation unit 17 calculates the root mean square RMS2 of the second current value I2, which was obtained in Step 4, in the window width W. The window width W used in this calculation is the window width W that was set in Step 2.

In Step 6, the Iu calculation unit 19 uses the root mean square RMS1 and the root mean square RMS2 calculated in Step 5 to calculate an imbalance current Iu. The imbalance current Iu is a value obtained by subtracting the root mean square RMS2 from the root mean square RMS1.

In Step 7, the change calculation unit 21 uses the imbalance current Iu calculated in Step 6 to calculate an amount of change ΔIu. The amount of change ΔIu is a value represented by Formula 1 below.

$$\begin{matrix}〈 Formula 1 〉 & \\ Δ Iu = \frac{Iu ( t ) - Iu ( t - Δt )}{Δ t} & ( fomula 1 )\end{matrix}$$

In Formula 1, Iu(t) is the imbalance current Iu calculated in previous Step 6, and Iu(t−Δt) is the imbalance current Iu calculated in Step 6 which is one cycle earlier than when Iu(t) is calculated. As described above, Δt is a cycle in which a process shown in FIG. 3 is executed, which is a cycle in which Step 6 is executed. The amount of change ΔIu is an amount of change per unit time in the imbalance current Iu.

In Step 8, the average calculation unit 23 uses the amount of change ΔIu calculated in Step 7 to calculate a time average value aveΔIu. The time average value aveΔIu is an amount represented by Formula 2 below.

$$\begin{matrix}〈 Formula 2 〉 & \\ ave Δ Iu = \frac{\sum \vert Δ Iu \vert}{P} & ( fomula 2 )\end{matrix}$$

A numerator on the right side in Formula 2 is an integration value obtained by integrating absolute values of all the amounts of change ΔIu calculated in an integration interval. The integration interval starts from a point in time going back by time P from execution of Step 8, and ends at a point in time when Step 8 is executed. The integration interval has a length of the time P. The time P is a positive value, for example, 2 seconds. The time P is longer than Δt. Therefore, in the integration interval, Step 7 is repeated more than once and a plurality of amounts of change ΔIu are calculated. The time average value aveΔIu is a time average value in the time P, of the absolute values of the amounts of change ΔIu.

In Step 9, the determining unit 25 compares the time average value aveΔIu calculated in Step 8 and the threshold value TH set in Step 3. When the determining unit 25 determines that the time average value aveΔIu is larger than the threshold value TH, the process proceeds to Step 10. On the other hand, when the determining unit 25 determines that the time average value aveΔIu is equal to or smaller than the threshold value TH, the present process ends.

In Step 10, the signal output unit 27 outputs the abnormality signal.

3. Effect

(1A) The collected current monitoring device 1 can output the abnormality signal when the first current collector 35 or the second current collector 37 is in a situation in which a large electric arc is likely to occur (hereinafter, referred to as large arc situation). Also, the collected current monitoring device 1 can control output of the abnormality signal when the first current collector 35 and the second current collector 37 are in a situation in which the large electric arc is unlikely to occur (hereinafter, referred to as normal situation).

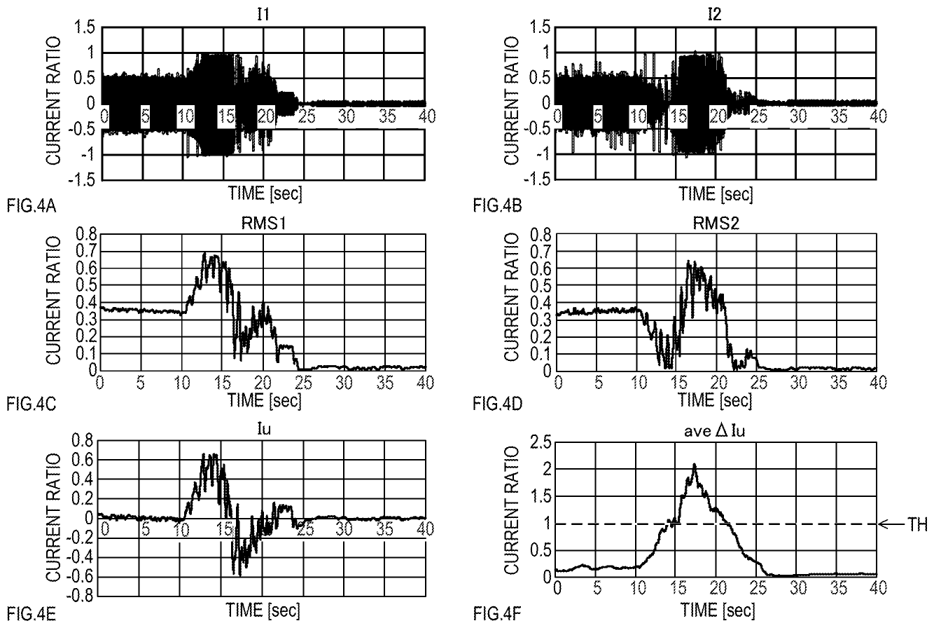

This will be explained based on experimental data below. In the large arc situation in which the overhead catenary line is frozen or frosted, the first current I1 was obtained as shown in FIG. 4A, and the second current I2 was obtained as shown in FIG. 4B. Then, the root mean square RMS1 was calculated from the first current I11 as shown in FIG. 4C, and the root mean square RMS2 was calculated from the second current I2 as shown in FIG. 4D.

Thereafter, as shown in FIG. 4E, the imbalance current Iu was calculated. Then, as shown in FIG. 4F, the time average value aveΔIu was calculated. As shown in FIG. 4F, in the large are situation, the time average value aveΔIu larger than the threshold value TH was generated. Thus, in case of the large arc situation, positive determination was made by the determining unit 25 in Step 9 and the abnormality signal was outputted by the signal output unit 27 in Step 10.

The reason why the time average value aveΔIu is likely to be large in the large arc situation may be because the imbalance current Iu fluctuates in a short cycle, as shown in FIG. 4E.

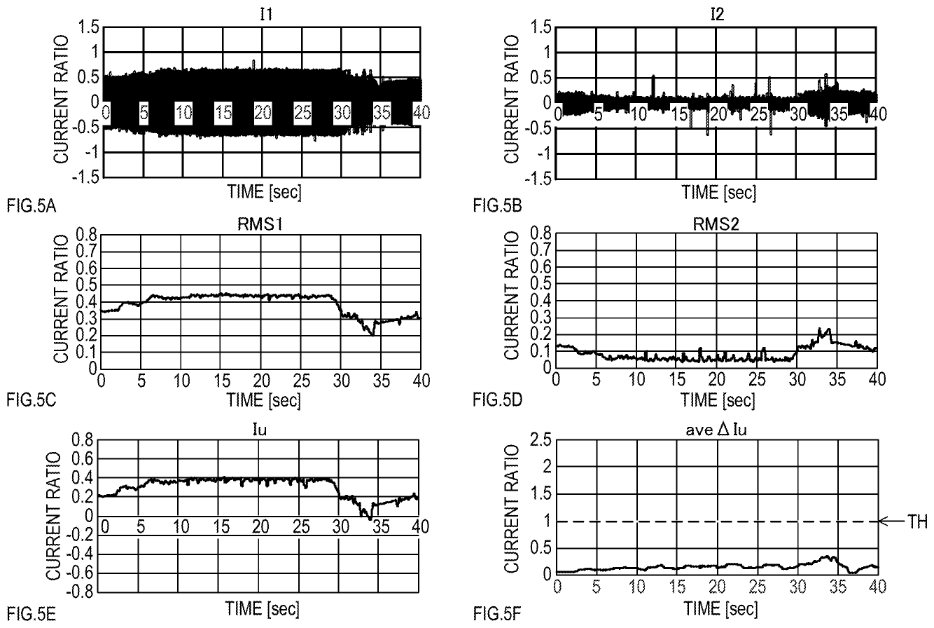

Also, in the normal situation in which the overhead catenary line is not frozen or frosted, the first current I1 was obtained as shown in FIG. 5A and the second current I2 was obtained as shown in FIG. 5B. Thereafter, the root mean square RMS1 was calculated from the first current I1 as shown in FIG. 5C and the root mean square RMS2 was calculated from the second current I2 as shown in FIG. 5D.

Then, as shown in FIG. 5E, the imbalance current Iu was calculated. Thereafter, as shown in FIG. 5F, the time average value aveΔIu was calculated. As shown in FIG. 5F, in the normal situation, the value of the time average value aveΔIu was small and was equal to or smaller than the threshold value TH at all time. Therefore, in case of the normal situation, negative determination was made at all time by the determining unit 25 in Step 9. The process was terminated without output of the abnormality signal.

Note that “current ratio” in FIGS. 4A to 4F and 5A to 5F is a current value standardized when the maximum current value in the large arc situation is 1 (one).

(1B) The average calculation unit 23 integrates the absolute value of the amount of change ΔIu calculated during the integration interval to calculate the integration value, and divides the integration value by the time P to calculate the time average value aveΔIu. In this manner, the time average value aveΔIu can be easily and precisely calculated.

### Second Embodiment

1. Difference from First Embodiment

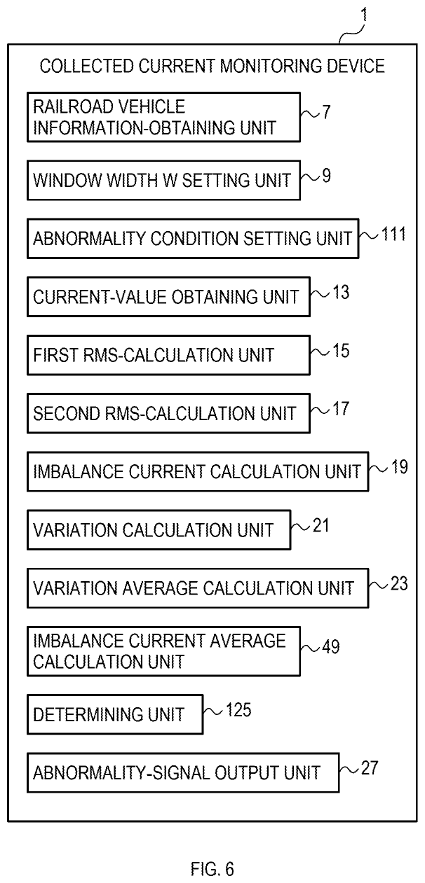

The second embodiment has the same basic configuration as the first embodiment. Thus, the difference from the first embodiment will be described below. The same reference numerals as those of the first embodiment indicate the same components and the preceding description is referred to. As shown in FIG. 6, the collected current monitoring device 1 further has an imbalance current average calculation unit (hereinafter, referred to as Iu average calculation unit) 49. Also, the collected current monitoring device 1 has a condition setting unit 111, in place of the condition setting unit 11, and a determining unit 125, in place of the determining unit 25.

2. Process Executed by Collected Current Monitoring Device 1

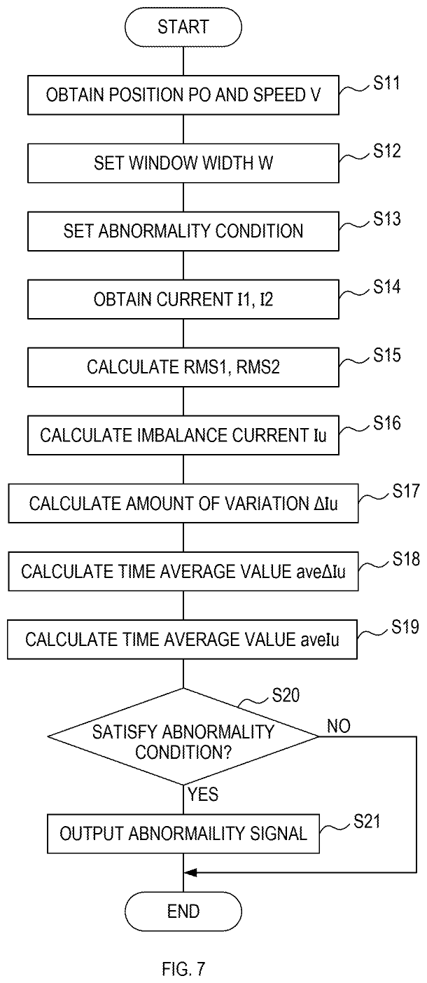

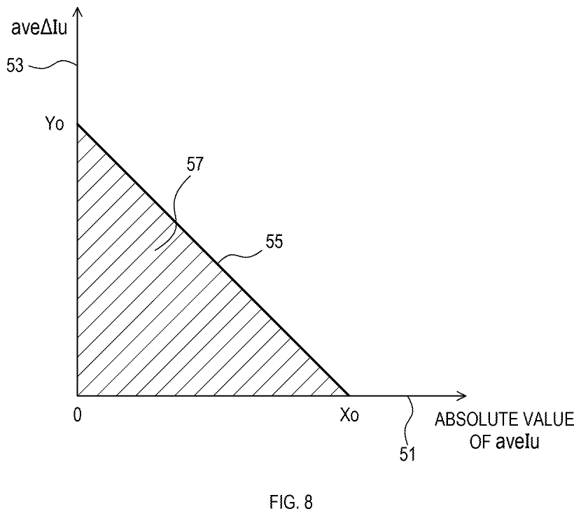

Process repeated by the collected current monitoring device 1 every fixed cycle Δt will be explained with reference to FIGS. 7 and 8. Steps 11 and 12 in FIG. 7 are the same as Steps 1 and 2 of the first embodiment.

In Step 13, the condition setting unit 111 sets an abnormality condition in accordance with the position PO and the speed V obtained in Step 11. The abnormality condition will be used in Step 20 described later. The abnormality condition is a condition that a combination of a time average value aveIu and the time average value aveΔIu is outside a normal region defined below. The time average value aveIu will be described later.

The abnormality condition and the normal region will be described with reference to FIG. 8. FIG. 8 shows a two-dimensional space defined by a first axis 51 representing an absolute value of the time average value aveIu, and a second axis 53 representing the time average value aveΔIu. Note that X0 is a positive intercept in the first axis 51, and Y0 is a positive intercept in the second axis 53. Reference numeral 55 indicates a boundary line passing through the intercept X0 and the intercept Y0. The boundary line 55 is, for example, a straight line. The normal region 57 is a region surrounded by the boundary line 55, the first axis 51, and the second axis 53.

In the two-dimensional space shown in FIG. 8, the abnormality condition is satisfied when a point obtained by plotting the combination of the time average value aveIu and the time average value aveΔIu is outside the normal region 57. On the other hand, the abnormality condition is not satisfied when the point obtained by plotting the combination of the time average value aveIu and the time average value aveΔIu is inside the normal region 57. The condition setting unit 111 has, in advance, a table which associates the position PO and the speed V with the abnormality condition, and uses the table to set the abnormality condition.

The table can be created, for example, by first creating a base table and then repeating a cycle of using the base table, assessing the result of the use, and revising the base table based on the assessment result. Revision in this cycle is made so that the abnormality condition is likely to be satisfied in the large arc situation, and the abnormality condition is unlikely to be satisfied in the normal situation.

Steps 14 to 18 in FIG. 7 are the same as Steps 4 to 8 of the first embodiment.

In Step 19, the Iu average calculation unit 49 uses the imbalance current Iu calculated in Step 16 to calculate the time average value aveIu. The time average value aveIu is an amount represented by Formula 3 below.

$$\begin{matrix}〈 Formula 3 〉 & \\ ave Iu = \frac{\sum Iu}{Q} & ( fomula 3 )\end{matrix}$$

A numerator on the right side in Formula 3 is an integration value obtained by integrating all the imbalance currents Iu calculated in an integration interval. The integration interval starts from a point in time going back by time Q from execution of Step 19, and ends at a point in time when Step 9 is executed. The integration interval has a length of the time Q. The time Q is a positive value, for example, 2 seconds. The time Q is longer than Δt. Therefore, in the integration interval, Step 16 is repeated more than once and a plurality of imbalance currents Iu are calculated. The time average value aveIu is a time average value in the time Q, of the imbalance currents Iu.

In Step 20, the determining unit 125 determines whether the combination of the time average value aveΔIu calculated in Step 18 and the time average value aveIu calculated in Step 19 satisfies the abnormality condition set in Step 13. When the determining unit 125 determines that the abnormality condition is satisfied, the process proceeds to Step 21. On the other hand, when the determining unit 125 determines that the abnormality condition is not satisfied, the present process ends.

In Step 21, the signal output unit 27 outputs the abnormality signal.

3. Effect

The second embodiment detailed above produces the effect (1B) of the first embodiment and further produces the following effect.

(2A) The collected current monitoring device 1, when in the large arc situation, can output the abnormality signal. Also, the collected current monitoring device 1, when in the normal situation, can control output of the abnormality signal.

This will be explained based on experimental data below. In the large arc situation in which the overhead catenary line is frozen or frosted, the first current I1 was obtained as shown in FIG. 4A, and the second current I2 was obtained as shown in FIG. 4B. Using the obtained values, the imbalance current Iu and the time average value aveΔIu were calculated as in the first embodiment. Further, using the imbalance current Iu, the time average value aveIu was calculated.

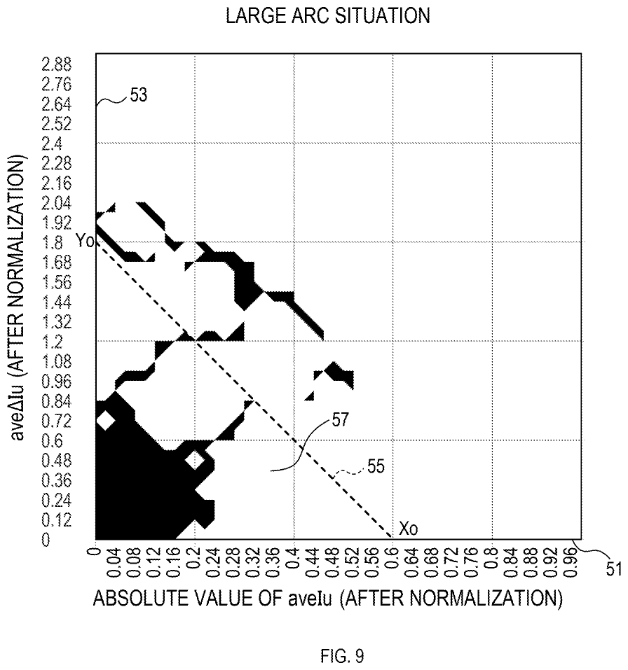

As shown in FIG. 9, a combination of the calculated time average value aveIu and time average value aveΔIu was plotted on the two-dimensional space defined by the first axis 51 and the second axis 53. In the large arc situation, some of the plotted points were located outside the normal region 57. Thus, in case of the large arc situation, positive determination was made by the determining unit 125 in Step 20, and the abnormality signal was outputted by the signal output unit 27 in Step 21.

Also, in the normal situation in which the overhead catenary line is not frozen or frosted, the first current I1 was obtained as shown in FIG. 5A, and the second current I2 was obtained as shown in FIG. 5B. Using the obtained values, the imbalance current Iu and the time average value aveΔIu were calculated as in the first embodiment. Further, using the imbalance current Iu, the time average value aveIu was calculated.

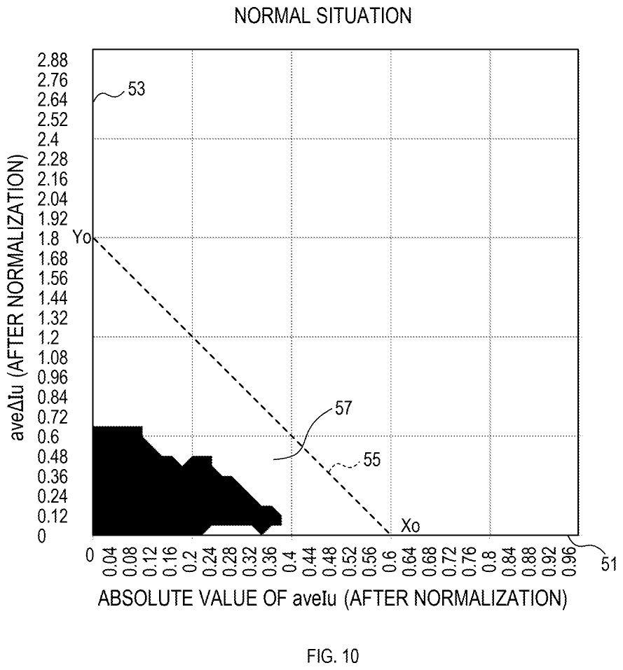

As shown in FIG. 10, the combination of the calculated time average value aveIu and time average value aveΔIu was plotted on the two-dimensional space defined by the first axis 51 and the second axis 53. In the normal situation, all the plotted points were located inside the normal region 57. Thus, in case of the normal situation, negative determination was made at all time by the determining unit 125 in Step 20. The process was terminated without output of the abnormality signal.

Note that the unit of the first axis 51 in FIGS. 9 and 10 is a current value standardized when the maximum current value in the large arc situation is 1 (one). Also, the unit of the second axis 53 in FIGS. 9 and 10 is a current value standardized when the maximum current value in the large arc situation is 1 (one).

(2B) The boundary line 55 is the straight line which passes through the intercept X0 and the intercept Y0. Therefore, it is easy to set the abnormality condition. Also, it is easy to determine whether the abnormality condition is satisfied.

### Third Embodiment

1. Difference from Second Embodiment

The third embodiment has the same basic configuration as the second embodiment. Thus, the difference from the first embodiment will be described below. The same reference numerals as those of the second embodiment indicate the same components and the preceding description is referred to.

In the third embodiment, in Step 13, the abnormality condition is set in accordance with the position PO and the speed V obtained by the condition setting unit 111 in Step 11. The abnormality condition is a condition that, in a two-dimensional space defined by a first axis representing a time average value ave|Iu| and a second axis representing the time average value aveΔIu, a combination of the time average value ave|Iu| and the time average value aveΔIu is outside a normal region defined below. The time average value ave|Iu| will be described later.

Normal region: a region surrounded by a boundary line passing through a positive intercept in the first axis and a positive intercept in the second axis, the first axis, and the second axis.

In the third embodiment, the time average value ave|Iu| is calculated in in Step 19. The time average value ave|Iu| is an amount represented by Formula 4 below.

$$\begin{matrix}〈 Formula 4 〉 & \\ ave \vert Iu \vert = \frac{\sum \vert Iu \vert}{Q} & ( fomula 4 )\end{matrix}$$

A numerator on the right side in Formula 4 is an integration value obtained by integrating absolute values of all the imbalance currents Iu calculated in an integration interval. The integration interval starts from a point in time going back by time Q from execution of Step 19, and ends at a point in time when Step 19 is executed. The integration interval has a length of the time Q. The time Q is a positive value, for example, 2 seconds. The time Q is longer than Δt. Therefore, in the integration interval, Step 16 is repeated more than once and a plurality of imbalance currents Iu are calculated. The time average value ave|Iu| is a time average value in the time Q, of the absolute values of the imbalance currents Iu.

In the third embodiment, in Step 20, the determining unit 125 whether the combination of the time average value aveΔIu calculated in Step 18 and the time average value ave|Iu| calculated in Step 19 satisfies the abnormality condition set in Step 13. When the determining unit 125 determines that the abnormality condition is satisfied, the process proceeds to Step 21. On the other hand, when the determining unit 125 determines that the abnormality condition is not satisfied, the present process ends.

2. Effect

The third embodiment detailed above produces the same effects as those of the second embodiment.

### Other Embodiments

The embodiments of the present disclosure have been described above. However, the present disclosure is not limited to the above-described embodiments and can be modified variously.

(1) In the first embodiment, the threshold value TH may be a fixed value. Also, in the second and the third embodiments, the abnormality condition may be a fixed condition.

(2) The length of the time P and the time Q can be set as needed. For example, the length of the time P and the time Q can be 0.1 seconds to 100 seconds, preferably 1 second to 10 seconds. When the length of the time P and the time Q are inside these ranges, output of the abnormality signal can be all the more controlled in the normal situation. The time P and the time Q may have the same length or may have different lengths.

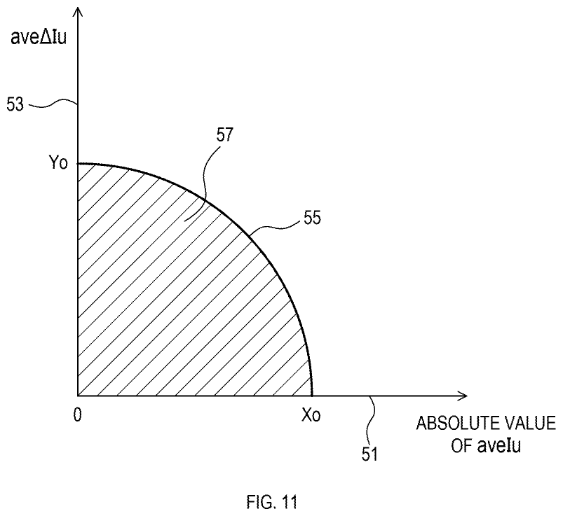

(3) The boundary line 55 may have a shape other than a straight line. For example, as shown in FIG. 11, the boundary line 55 may have a curved shape.

(4) The imbalance current Iu may be a value obtained by subtracting the root mean square RMS1 from the root mean square RMS2.

(5) The determination in Step 9 may be executed in a different manner. For example, among the plurality of time average values aveΔIu, positive determination may be made when the number or ratio of those larger than the threshold value TH is equal to or larger than a specified reference value. Otherwise, negative determination may be made.

(6) The determination in Step 20 of the second embodiment may be executed in a different manner. For example, among the combinations of the time average values aveΔIu and the time average values aveIu, positive determination may be made when the number or ratio of those that satisfy the abnormality condition is equal to larger than a specified reference value. Otherwise, negative determination may be made.

The determination in Step 20 of the third embodiment may be executed in a different manner. For example, among the combinations of the time average values aveΔIu and the time average values ave|Iu|, positive determination may be made when the number or ratio of those that satisfy the abnormality condition is larger than a specified value. Otherwise, negative determination may be made.

(7) Δt can have a set length as needed. For example, the length of Δt can be 0.01 msec to 100 msec, preferably 0.1 msec to 10 msec. When the length of Δt is inside these ranges, output of the abnormality signal can be all the more reliably outputted.

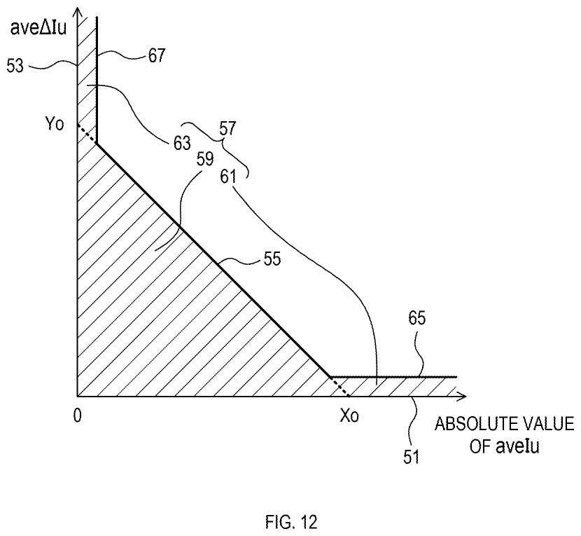

(8) The normal region 57 may take other forms. For example, as shown in FIG. 12, the normal region 57 may be a region including a first region 59, a second region 61, and a third region 63. The first region 59 is a region surrounded by the boundary line 55, the first axis 51 and the second axis 53. The second region 61 is a region between the first axis 51 and a boundary line 65 parallel to the first axis 51, excluding the first region 59. The third region 63 is a region between the second axis 53 and a boundary line 67 parallel to the second axis 53, excluding the first region 59.

(9) A function achieved by one element in the aforementioned embodiment may be shared by two or more elements. A function achieved by two or more elements may be demonstrated by one element. Further, a part of the configuration of any of the aforementioned embodiments may be omitted. At least a part of the configuration of any of the aforementioned embodiments may be added to or replaced with the configuration of the aforementioned other embodiments. It should be noted that any and all modes that are encompassed in the technical ideas defined by the languages in the scope of the claims are embodiments of the present disclosure.

(10) The present disclosure may be practiced in various modes. Such modes include, other than the above-described collected current monitoring device, a system comprising the collected current monitoring device as a component, a program enabling a computer to function as the other than the above-described collected current monitoring device, a non-transitory tangible recording medium, such as a semiconductor memory storing the aforementioned program, and a method used in the collected current monitoring device.

What is claimed is:

1. A collected current monitoring device comprising:
a current-value obtaining unit that obtains a current value I1 of collected current flowing through a first current collector, and a current value I2 of collected current flowing through a second current collector;
a first RMS-calculation unit that calculates a root mean square RMS1 of the current value I1;
a second RMS-calculation unit that calculates a root mean square RMS2 of the current value I2;
an Iu calculation unit that calculates an imbalance current Iu, the imbalance current Iu being a value obtained by subtracting one of the root mean square RMS1 and the root mean square RMS2 from the other;
a change calculation unit that calculates an amount of change ΔIu, the amount of change ΔIu being an amount of change per unit time in the imbalance current Iu;
an average calculation unit that calculates a time average value aveΔIu, the time average value aveΔIu being a time average value in a preset time P, of an absolute value of the amount of change ΔIu;
a determining unit that determines whether the time average value aveΔIu is larger than a preset threshold value; and
a signal output unit that outputs an abnormality signal when the determining unit determines that the time average value aveΔIu is larger than the threshold value.

2. A collected current monitoring device comprising:
a current-value obtaining unit that obtains a current value I1 of collected current flowing through a first current collector, and a current value I2 of collected current flowing through a second current collector;
a first RMS-calculation unit that calculates a root mean square RMS1 of the current value I1;
a second RMS-calculation unit that calculates a root mean square RMS2 of the current value I2;
an Iu calculation unit that calculates an imbalance current Iu, the imbalance current Iu being a value obtained by subtracting one of the root mean square RMS1 and the root mean square RMS2 from the other;
a change calculation unit that calculates an amount of change ΔIu, the amount of change ΔIu being an amount of change per unit time in the imbalance current Iu;
an average calculation unit that calculates a time average value aveΔIu, the time average value aveΔIu being a time average value in a preset time P, of an absolute value of the amount of change ΔIu;
an Iu average calculation unit that calculates a time average value aveIu, the time average value aveIu being a time average value in a preset time Q, of the imbalance current Iu;
a determining unit that determines whether a combination of the time average value aveIu and the time average value aveΔIu satisfies a preset abnormality condition; and
a signal output unit that outputs an abnormality signal when the determining unit determines that the combination satisfies the abnormality condition,
the abnormality condition being a condition that, in a two-dimensional space defined by a first axis representing the absolute value of the time average value aveIu and a second axis representing the time average value aveΔIu, the combination of the time average value aveIu and the time average value aveΔIu is outside a normal region, the normal region including a region surrounded by a boundary line passing through a positive intercept in the first axis and a positive intercept in the second axis, the first axis, and the second axis.

3. A collected current monitoring device comprising:
a current-value obtaining unit that obtains a current value I1 of collected current flowing through a first current collector, and a current value I2 of collected current flowing through a second current collector;
a first RMS-calculation unit that calculates a root mean square RMS1 of the current value I1;
a second RMS-calculation unit that calculates a root mean square RMS2 of the current value I2;
an Iu calculation unit that calculates an imbalance current Iu, the imbalance current Iu being a value obtained by subtracting one of the root mean square RMS1 and the root mean square RMS2 from the other;
a change calculation unit that calculates an amount of change ΔIu, the amount of change ΔIu being an amount of change per unit time in the imbalance current Iu;
an average calculation unit that calculates a time average value aveΔIu, the time average value aveΔIu being a time average value in a preset time P, of an absolute value of the amount of change ΔIu;
an Iu average calculation unit that calculates a time average value ave|Iu|, the time average value ave|Iu| being a time average value in a preset time Q, of an absolute value of the imbalance current Iu;
a determining unit that determines whether a combination of the time average value ave|Iu| and the time average value aveΔIu satisfies a preset abnormality condition; and
a signal output unit that outputs an abnormality signal when the determining unit determines that the combination satisfies the abnormality condition,
the abnormality condition being a condition that, in a two-dimensional space defined by a first axis representing the time average value ave|Iu| and a second axis representing the time average value aveΔIu, the combination of the time average value ave|Iu| and the time average value aveΔIu is outside a normal region, the normal region including a region surrounded by a boundary line passing through a positive intercept in the first axis and a positive intercept in the second axis, the first axis, and the second axis.

4. The collected current monitoring device according to claim 2,
wherein the boundary line is a straight line passing through the positive intercept in the first axis and the positive intercept in the second axis.

5. The collected current monitoring device according to claim 1,
wherein the average calculation unit is configured to integrate the absolute value of the amount of change ΔIu calculated in the time P to obtain an integration value, and divide the integration value by the time P to calculate the time average value aveΔIu.
